(19) United States
(12) Patent Application Publication
(10) Pub. No.: US 2010/0207266 A1
(43) Pub. Date: Aug. 19, 2010

(54) CHIP PACKAGE STRUCTURE

(75) Inventors: Tao-Chih Chang, Taoyuan County (TW); Su-Tsai Lu, Hsinchu City (TW); Chau-Jie Zhan, Taipei County (TW); Chun-Chih Chuang, Taichung City (TW); Jing-Ye Juang, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: INDUSTRIAL TECHNOLOGY RESEARCH INSTITUTE, Hsinchu (TW)

(21) Appl. No.: 12/426,967

(22) Filed: Apr. 21, 2009

(30) Foreign Application Priority Data
Feb. 16, 2009 (TW) 98104827

(51) Int. Cl. H01L 23/52

(52) U.S. Cl. 257/692; 257/737; 257/741; 257/E23.141; 257/E23.01

(57) ABSTRACT

A chip package structure including a substrate, a plurality of electrodes, a chip, and a plurality of bumps is provided. Each of the electrodes has a bottom portion and an annular element, wherein the bottom portion is disposed on the substrate, the annular element is disposed on the bottom portion, and the bottom portion and the annular element define a containing recess. The chip is disposed above the substrate and has an active surface facing the substrate and a plurality of pads disposed on the active surface. The bumps are respectively disposed on the pads and respectively inserted into the containing recesses. The melting point of the electrodes is higher than that of the bumps. A chip package method is also provided.

### CROSS-REFERENCE TO RELATED APPLICATION

This application claims the priority benefit of Taiwan application serial no. 98104827, filed on Feb. 16, 2009. The entirety of the above-mentioned patent application is hereby incorporated by reference herein and made a part of this specification.

### BACKGROUND OF THE INVENTION

1. Field of the Invention

The present invention generally relates to an electronic device and a package method, and more particularly, to a chip package structure and a chip package method.

2. Description of Related Art

Usually, a semiconductor chip does not exist by itself but is connected to other chips or circuits through its input/output system. Besides, a semiconductor chip usually has a very complicated internal circuit which needs to be packaged into a chip package to be protected and carried around. The major functions of a chip package includes: (1) providing a current path to drive the circuit in the chip; (2) distributing input/output signals of the chip; (3) dissipating the heat generated by the circuit in the chip; and (4) protecting the chip in a devastating environment.

Presently, different kinds of carriers (for example, lead frames and circuit substrates) are used in chip packages and accordingly different package structures are formed. In recently years, the integrated density of semiconductor chips has been gradually increased and accordingly the number of electronic products offering diversified functionality, large capacity, high processing speed, and small area has been increased. Correspondingly, the chip packaging technology is also going towards high density, high pin count, high frequency, and high performance.

Among various chip packaging technologies, the flip chip (FC) bonding technology is the most adaptable one to high-level chip packaging, wherein a plurality of bumping pads is disposed on an active surface of a chip as an area array, and bumps are then formed on these bumping pads. After that, the chip is flipped and the bumping pads on the active surface of the chip are electrically and structurally connected to the contacts on a carrier respectively through these bumps, so that the chip can be electrically connected to the carrier through these bumps and accordingly to an external electronic device through internal circuit of the carrier.

The FC bonding technology is suitable for a chip package structure having a high pin count and it can reduce the area of the chip package structure and shorten the signal transmission path. Along with the advancement of chip packaging technology towards high pin count, the reliability of the contacts becomes more and more important because it may greatly affect the production yield and reliability of the chip package structure. Thereby, how to improve the reliability of contacts has become one of the major subjects in chip packaging technology.

### SUMMARY OF THE INVENTION

Accordingly, the present invention is directed to a chip package structure, wherein the bonding reliability between the electrodes on the substrate thereof and the bumps is improved.

According to an embodiment of the present invention, a chip package structure including a substrate, a plurality of electrodes, a chip, and a plurality of bumps is provided. Each of the electrodes has a bottom portion and an annular element, wherein the bottom portion is disposed on the substrate, the annular element is disposed on the bottom portion, and the bottom portion and the annular element define a containing recess. The chip is disposed above the substrate and has an active surface facing the substrate and a plurality of first pads disposed on the active surface. The bumps are respectively disposed on the first pads and inserted into the containing recesses, wherein the melting point of the electrodes is higher than that of the bumps.

According to another embodiment of the present invention, a chip package structure including a substrate, a plurality of electrodes, a chip, and a plurality of bumps is provided. Each of the electrodes has a bottom portion and an annular element. The bottom portion is disposed on the substrate. The annular element includes a first metal ring and a second metal ring. The first metal ring is disposed on the bottom portion. The second metal ring is disposed on the bottom portion and is connected to the inside of the first metal ring. The second metal ring and the bottom portion define a containing recess. The chip is disposed above the substrate and has an active surface facing the substrate and a plurality of first pads disposed on the active surface. The bumps are respectively disposed on the first pads and respectively inserted into the containing recesses. The melting point of the electrodes is higher than that of the bumps.

According to yet another embodiment of the present invention, a chip package structure including a substrate, a plurality of electrodes, a chip, a plurality of bumps, and a resin is provided. Each of the electrodes has a bottom portion and an annular element, wherein the bottom portion is disposed on the substrate, the annular element is disposed on the bottom portion, and the bottom portion and the annular element define a containing recess. The chip is disposed above the substrate and has an active surface facing the substrate and a plurality of first pads disposed on the active surface. The bumps are respectively disposed on the first pads and respectively inserted into the containing recesses. The resin is disposed between the substrate and the chip and encapsulates the electrodes and the bumps. The resin supplies a pressure to each of the annular elements to bend one end of the annular element which is away from the bottom portion towards the corresponding bump and hold the bump.

As described above, in the chip package structure according to the embodiment of the present invention, the bumps are disposed in the annular elements of the electrodes so that the annular elements of the electrodes can hold the bumps through thermal stress or the hydraulic pressure supplied by the resin to the annular elements. As a result, the bonding reliability between the electrodes and the bumps is improved.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a cross-sectional view of a chip package structure according to an embodiment of the present invention.

FIG. 1B is a top view of an electrode in FIG. 1A.

FIGS. 2A˜2D are top views of electrodes according to another four embodiments of the present invention.

FIG. 3A is a cross-sectional view of a chip package structure according to another embodiment of the present invention.

FIG. 3B is a top view of an electrode in FIG. 3A.

FIG. 4A is a cross-sectional view of a chip package structure according to yet another embodiment of the present invention.

FIG. 4B is a top view of an electrode in FIG. 4A.

FIG. 5A is a cross-sectional view of a chip package structure before a chip and a substrate are bonded according to still another embodiment of the present invention.

FIG. 5B is a cross-sectional view of the chip package structure in FIG. 5A after the chip and the substrate are bonded.

FIG. 6 is a cross-sectional view of a chip package structure according to yet still another embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

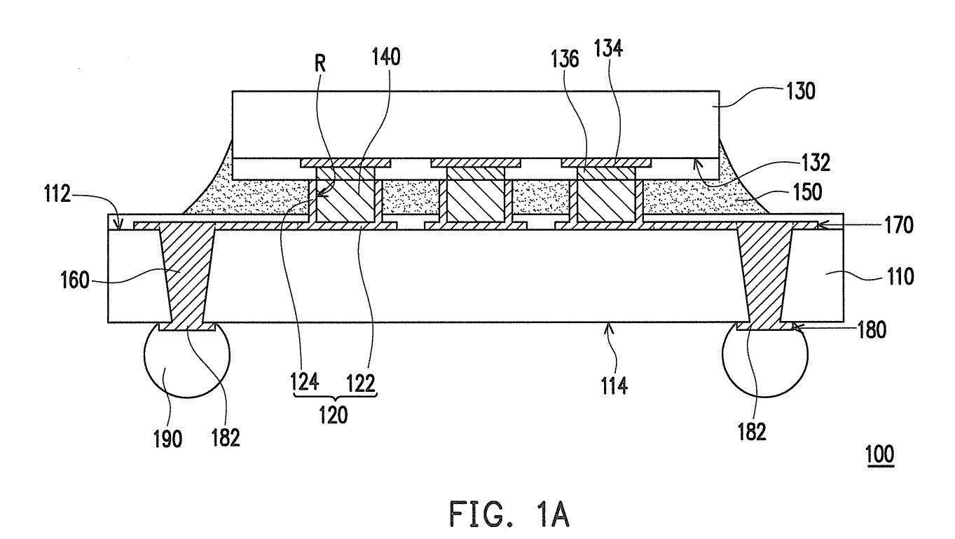

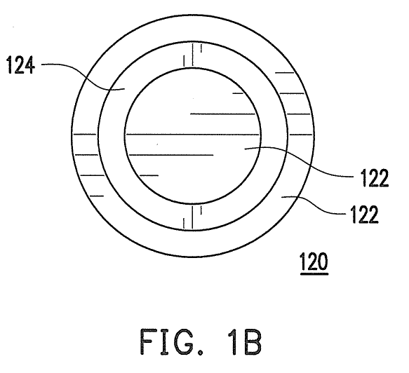

FIG. 1A is a cross-sectional view of a chip package structure according to an embodiment of the present invention, and FIG. 1B is a top view of an electrode in FIG. 1A. Referring to FIG. 1A and FIG. 1B, in the present embodiment, the chip package structure 100 includes a substrate 110 and a plurality of electrodes 120. The substrate 110 may be a circuit substrate. Each of the electrodes 120 has a bottom portion 122 and an annular element 124, wherein the bottom portion 122 is disposed on the substrate 110, the annular element 124 is disposed on the bottom portion 122, and the bottom portion 122 and the annular element 124 define a containing recess R.

The chip package structure 100 further includes a chip 130 and a plurality of bumps 140. The chip 130 is disposed above the substrate 110 and has an active surface 132 facing the substrate 110 and a plurality of pads 134 disposed on the active surface 132. The bumps 140 are respectively disposed on the pads 134. To be specific, the bumps 140 are respectively disposed on the pads 134 through a plurality of under bump metal (UBM) layers 136, namely, these UBM layers 136 respectively connect the bumps 140 and the pads 134. In addition, the bumps 140 are respectively inserted into the containing recesses R.

Before the bumps 140 and the electrodes 120 are bonded together, the width of each of the bumps 140 in the direction parallel to the active surface 132 may be smaller than or equal to the internal diameter of each annular element 124. In the present embodiment, the coefficient of thermal expansion (CTE) of the bumps 140 is higher than that of the electrodes 120. In other words, the CTE of the bumps 140 is higher than that of the annular elements 124. Thus, when the bumps 140 and the electrodes 120 are bonded together and accordingly the temperature of the chip package structure 100 increases, the bumps 140 expand and push the annular elements 124 outwards, namely, the annular elements 124 supply a holding counterforce to the bumps 140. Herein, the width of each of the bumps 140 in the direction parallel to the active surface 132 is equal to the internal diameter of each annular element 124. Accordingly, the bonding reliability between the bumps 140 and the electrodes 120 is effectively improved, and both the production yield and electrical quality of the chip package structure 100 are improved.

Additionally, in the present embodiment, the melting point of the electrodes 120 is higher than that of the bumps 140, which is advantageous in the bonding between the bumps 140 and the electrodes 120. Moreover, in the present embodiment, the bumps 140 are respectively bonded with the electrodes 120 through chemical bonding, wherein the material of the electrodes 120 includes at least one of copper and nickel, and the material of the bumps 140 includes stannum. However, in another embodiment of the present invention, the bumps 140 may also be respectively bonded with the electrodes 120 through physical contact, wherein the material of the electrodes 120 may include at least one of platinum, copper, and titanium, and the material of the bumps 140 may include gold and nickel.

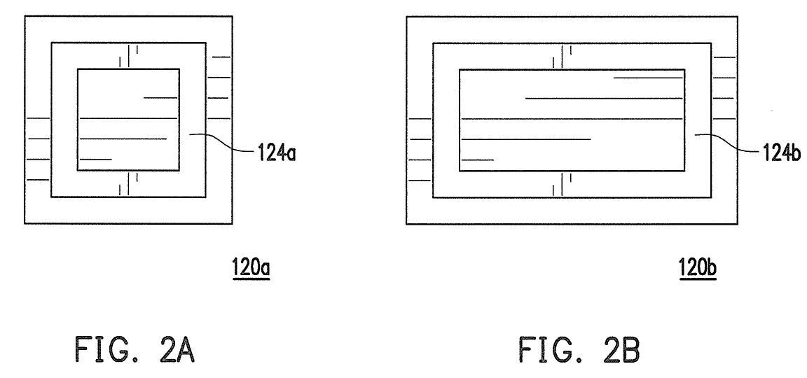

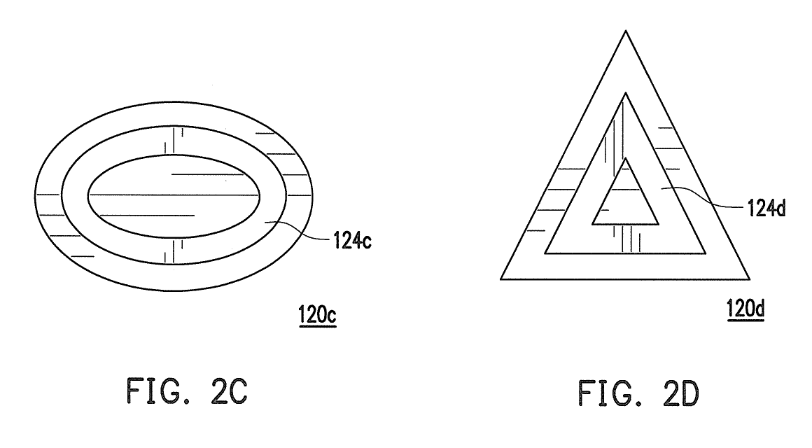

In the present embodiment, the annular elements 124 are circular annular elements, as shown in FIG. 1B. However, in another four embodiments of the present invention, the annular elements 124a, 124b, 124c, and 124d of the electrodes 120a, 120b, 120c, and 120d are respectively square annular elements, rectangular annular elements, oval annular elements, and triangle annular elements, as shown in FIGS. 2A, 2B, 2C, and 2D. In addition, in another embodiment of the present invention, the annular elements 124 may also be replaced by any other polygonal annular elements or annular elements of any other geometric shape.

In the present embodiment, the chip package structure 100 further includes a resin 150 which is disposed between the substrate 110 and the chip 130 and encapsulates the electrodes 120 and the bumps 140. The resin 150 is used for protecting the electrodes 120 and the bumps 140.

In the present embodiment, the substrate 110 has a first surface 112 and a second surface 114 opposite to each other, and the electrodes 120 are disposed on the first surface 112. In addition, in the present embodiment, the chip package structure 100 further has a plurality of conductive vias 160 which pass through the substrate 110 and are extended from the first surface 112 to the second surface 114. Besides, the conductive vias 160 are electrically connected to the electrodes 120.

To be specific, a first patterned conductive layer 170 is disposed on the first surface 112 of the substrate 110, wherein a part of the first patterned conductive layer 170 forms the bottom portions 122 of the electrodes 120, and the conductive vias 160 are connected to the first patterned conductive layer 170 so that the conductive vias 160 can be electrically connected to the electrodes 120. Besides, a second patterned conductive layer 180 is disposed on the second surface 114 of the substrate 110, wherein the second patterned conductive layer 180 forms a plurality of pads 182, and the pads 182 are electrically connected to the conductive vias 160. A plurality of solder balls 190 is further disposed on the pads 182, and the solder balls 190 may be connected to another circuit substrate (not shown). The conductive vias 160 are formed by filling a conductive material into a plurality of holes.

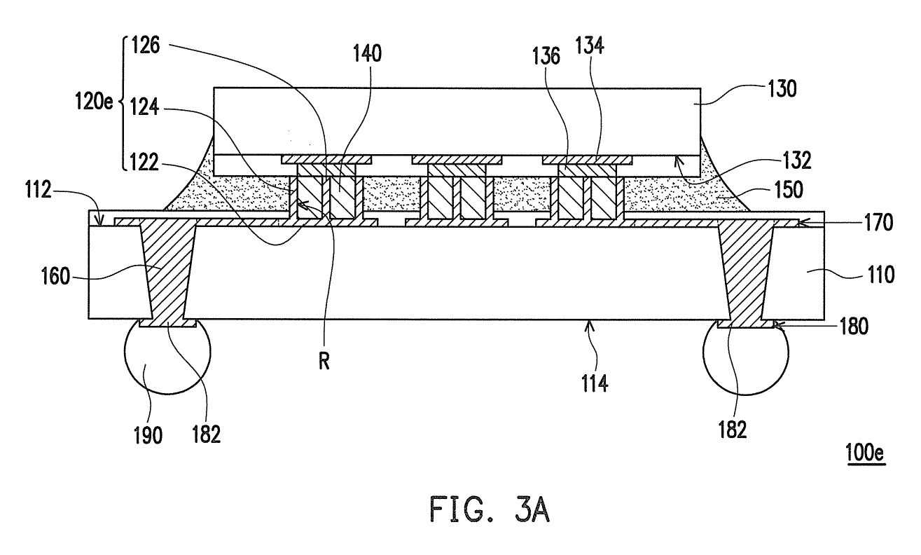

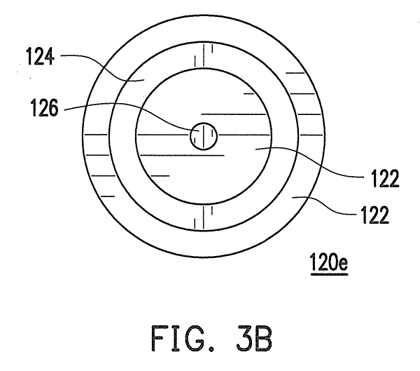

FIG. 3A is a cross-sectional view of a chip package structure according to another embodiment of the present invention, and FIG. 3B is a top view of an electrode in FIG. 3A. Referring to FIG. 3A and FIG. 3B, the chip package structure 100e in the present embodiment is similar to the chip package structure 100 (as shown in FIG. 1A) described above, and the difference between the two will be described hereinafter. In the chip package structure 100e, each of the electrodes 120e further includes a conductive pole 126, wherein the conductive pole 126 is disposed on the bottom portion 122 and located within the containing recess R of the annular element 124, and the conductive pole 126 is kept a distance away from the annular element 124. The disposition of the conductive poles 126 enhances the bonding strength between the bumps 140 and the electrodes 120e and accordingly improves the production yield and electrical quality of the chip package structure 100e.

In the present embodiment, the conductive poles 126 are circular columns. However, in another embodiment of the present invention, the conductive pole may also be square columns, rectangular columns, oval columns, triangular columns, or columns in any other geometric shape.

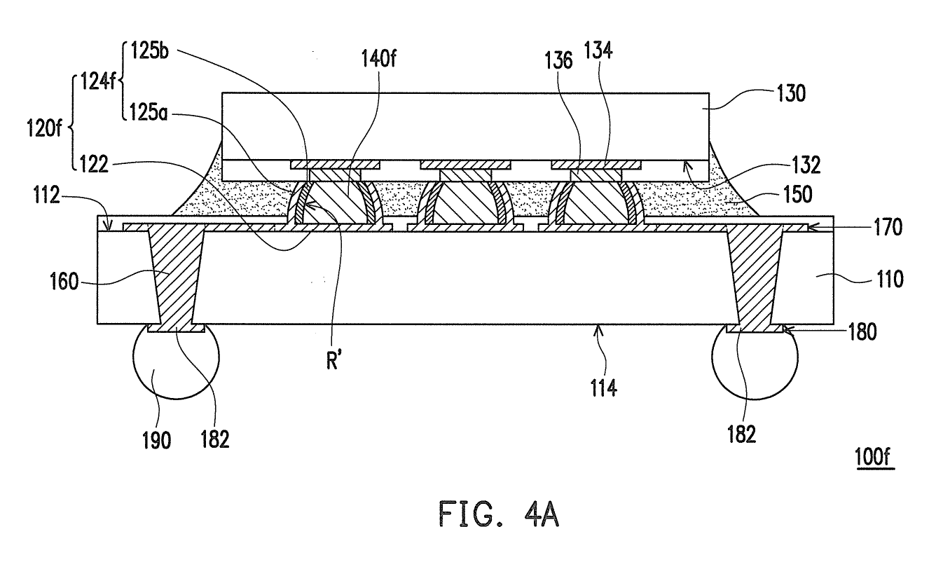

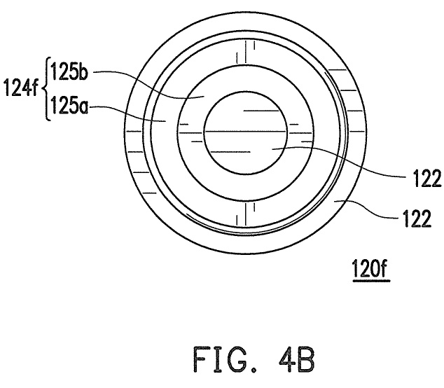

FIG. 4A is a cross-sectional view of a chip package structure according to yet another embodiment of the present invention, and FIG. 4B is a top view of an electrode in FIG. 4A. Referring to FIG. 4A and FIG. 4B, the chip package structure 100f in the present embodiment is similar to the chip package structure 100 (as shown in FIG. 1A) described above, and the difference between the two will be described hereinafter. In the chip package structure 100f, the annular element 124f of each of the electrodes 120f includes a first metal ring 125a and a second metal ring 125b, wherein the first metal ring 125a is disposed on the bottom portion 122, and the second metal ring 125b is disposed on the bottom portion 122 and connected to the inside of the first metal ring 125a.

The second metal ring 125b and the bottom portion 122 define a containing recess R′. In the present embodiment, the CTE of the first metal ring 125a is lower than that of the second metal ring 125b. Besides, in the present embodiment, the material of the first metal ring 125a and the second metal ring 125b may be a shape memory alloy.

Because the CTE of the first metal ring 125a is lower than that of the second metal ring 125b, when the chip package structure 100f is restored from a process temperature back to the room temperature, the second metal ring 125b shrinks more than the first metal ring 125a and accordingly the free end of the annular element 124f which is away from the bottom portion 122 is bent towards the corresponding bump 140f and accordingly supplies a holding force to the bump 140f to hold the bump 140f. Since the bump 140f is held by the annular element 124f, the bonding reliability between the bump 140f and the electrode 120f is effectively improved, and accordingly both the production yield and electrical quality of the chip package structure 100f are improved.

In the present embodiment, the annular elements 124f are circular annular elements, as shown in FIG. 4B. However, in another embodiment of the present invention, the annular elements 124f may also be square annular elements (similar to that illustrated in FIG. 2A), rectangular annular elements (similar to that illustrated in FIG. 2B), oval annular elements (similar to that illustrated in FIG. 2C), triangular annular elements (similar to that illustrated in FIG. 2D), or annular elements of any other geometric shape. In addition, the electrodes 120f may also include the conductive poles 126 as shown in FIG. 3A and FIG. 3B the detail of which is omitted herein.

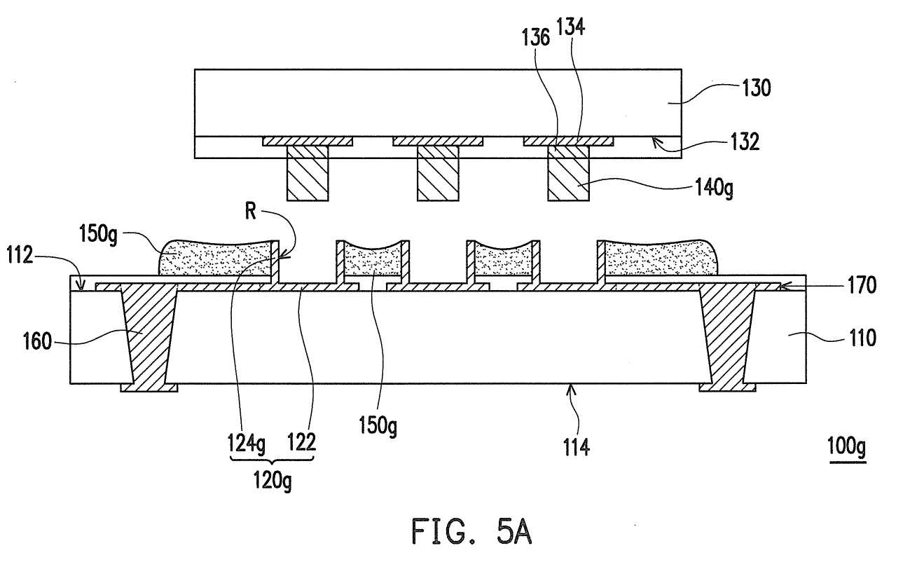

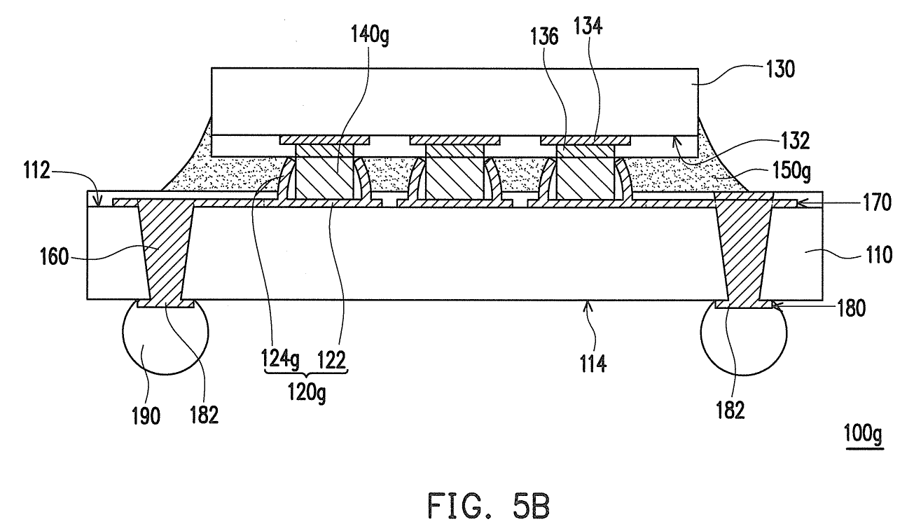

FIG. 5A is a cross-sectional view of a chip package structure before a chip and a substrate are bonded according to still another embodiment of the present invention, and FIG. 5B is a cross-sectional view of the chip package structure in FIG. 5A after the chip and the substrate are bonded. Referring to FIG. 5A and FIG. 5B, the chip package structure 100g in the present embodiment is similar to the chip package structure 100 (as shown in FIG. 1A) described above, and the difference between the two will be described hereinafter. In the chip package structure 100g, the resin 150g supplies a pressure to the sidewall of each annular element 124g such that the free end of the sidewall of the annular element 124g which is away from the bottom portion 122 is bent towards the corresponding bump 140g and holds the corresponding bump 140g. Namely, the electrode 120g and the bump 140g are bonded through physical contact.

In the present embodiment, the chip package method of the chip package structure 100g includes following steps. First, referring to FIG. 5A, the substrate 110 is provided. Then, a plurality of electrodes 120g is formed on the substrate 110, wherein the electrodes 120g are the same as the electrodes 120 illustrated in FIG. 1A. After that, a resin 150g is filled on the substrate 110, wherein the resin 150g encapsulates the electrodes 120g, and the average liquid height of the resin 150g is lower than the height of the free end of the annular element 124g of each of the electrodes 120g which is away from the bottom portion 122. In the present embodiment, the liquid height of the resin 150g at the place adjacent to each annular element 124g is substantially the same as the height of the free end of the annular element 124g which is away from the bottom portion 122, and the liquid height of the resin 150g gradually decreases from the electrodes 120 towards the positions between the electrodes 120. Besides, the chip 130 is provided. Next, a plurality of pads 134 is formed on the active surface 132 of the chip 130, and a plurality of bumps 140g is respectively disposed on the pads 134 of the chip 130.

Next, the active surface 132 of the chip 130 is placed towards the substrate 110, and the bumps 140g are respectively placed into the containing recesses R. In other words, the chip 130 and the substrate 110 are pressed together. In this case, the active surface 132 pushes the resin 150g so that the resin 150g supplies a pressure to each annular element 124g. As a result, the annular element 124g, after suffering the pressure, bends into a shape as shown in FIG. 5B, namely, the pressure that the resin 150g supplies to the annular element 124g causes the free end of the annular element 124g which is away from the bottom portion 122 to bend towards the corresponding bump 140g and hold this bump 140g. Thus, the bonding reliability between the bumps 140g and the electrodes 120g is effectively improved, and both the production yield and electrical quality of the chip package structure 100g are also improved. Thereafter, the resin 150g is solidified to complete the packaging process of the chip 130.

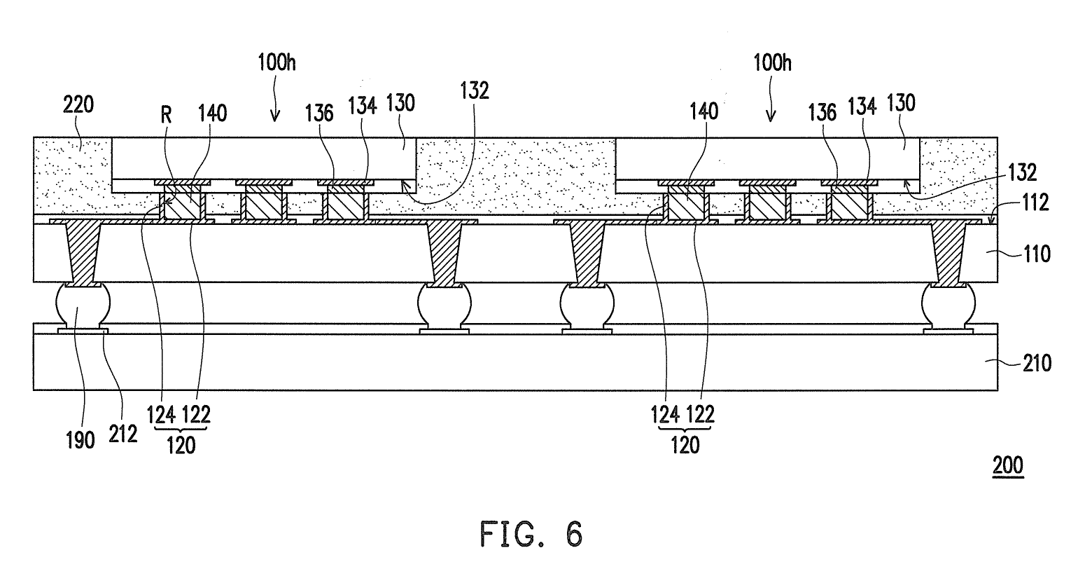

FIG. 6 is a cross-sectional view of a chip package structure according to yet still another embodiment of the present invention. Referring to FIG. 6, the chip package structure 200 in the present embodiment is similar to the chip package structure 100 illustrated in FIG. 1A, and the difference between the two will be described below. In the chip package structure 200, a plurality of chip package structures 100h is disposed on a circuit substrate 210, and the only difference between the chip package structure 100h and the chip package structure 100 illustrated in FIG. 1A is that the chip package structure 100h does not include the resin 150 in the chip package structure 100. In the present embodiment, the circuit substrate 210 may be a multi-layer circuit board. To be specific, in the chip package structure 100h, the solder balls 190 are disposed on the electrodes 212 of the circuit substrate 210 so that the chip package structure 100h can be electrically connected to the circuit substrate 210. The chip package structure 100h further includes a resin 220 which is disposed on the substrate 110 and encapsulates the bumps 140 and the electrodes 120. Because the chip package structure 100h offers good production yield and high electrical quality, the production yield and electrical quality of the chip package structure 200 are also improved.

It should be noted that the chip package structure 100h in the chip package structure 200 may also be replaced by any other chip package structure (for example, the chip package structure 100e, 100f, or 100g) in the above embodiments to form a different chip package structure.

As described above, in the chip package structure according to the embodiments of the present invention, the bumps are disposed within the annular elements of the electrodes so that the bumps can be held by the annular elements because of different CTEs of the bumps and the annular elements. As a result, the bonding reliability between the electrodes and the bumps is improved, and accordingly the production yield and electrical quality of the chip package structure are both improved.

In the chip package structure according to the embodiments of the present invention, because the materials for forming the first metal rings and the second metal rings of the annular elements have different CTEs, once the temperature of the chip package structure is reduced, the free ends of the annular elements away from the substrate bend towards the corresponding bumps so that the bumps are held by the annular elements. As a result, the bonding reliability between the electrodes and the bumps is improved.

In the chip package structure and chip package method according to the embodiments of the present invention, the resin supplies a pressure to each annular element so that the free end of the annular element which is away from the bottom portion bends towards the corresponding bump to hold the bump. As a result, the bonding reliability between the electrodes and the bumps is improved.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A chip package structure, comprising:
a substrate;
a plurality of electrodes, wherein each of the electrodes comprises:
a bottom portion, disposed on the substrate; and
an annular element, disposed on the bottom portion, wherein the bottom portion and the annular element define a containing recess;
a chip, disposed above the substrate, and having an active surface facing the substrate and a plurality of first pads disposed on the active surface; and
a plurality of bumps, respectively disposed on the first pads and respectively inserted into the containing recesses, wherein a melting point of the electrodes is higher than a melting point of the bumps.

2. The chip package structure according to claim 1 further comprising a plurality of under bump metal (UBM) layers respectively connecting the bumps and the first pads.

3. The chip package structure according to claim 1, wherein a width of the bump in a direction parallel to the active surface is equal to or smaller than an internal diameter of the annular element.

4. The chip package structure according to claim 1, wherein a coefficient of thermal expansion (CTE) of the bumps is higher than a CTE of the electrodes.

5. The chip package structure according to claim 1, wherein the annular element is a polygonal annular element, a circular annular element, or an oval annular element.

6. The chip package structure according to claim 1, wherein each of the electrodes further comprises a conductive pole disposed on the bottom portion and located within the containing recess, and the conductive pole is kept a distance away from the annular element.

7. The chip package structure according to claim 1 further comprising a resin, wherein the resin is disposed between the substrate and the chip and encapsulates the electrodes and the bumps.

8. The chip package structure according to claim 1, wherein the substrate has a first surface and a second surface opposite to each other, the electrodes are disposed on the first surface, the chip package structure further comprises a plurality of conductive vias, the conductive vias pass through the substrate and are extended from the first surface to the second surface, and the conductive vias are electrically connected to the electrodes.

9. The chip package structure according to claim 1, wherein the bumps are respectively bonded with the electrodes through chemical bonding.

10. The chip package structure according to claim 9, wherein a material of the electrodes comprises at least one of copper and nickel, and a material of the bumps comprises stannum.

11. The chip package structure according to claim 1, wherein the bumps are respectively bonded with the electrodes through physical contact.

12. The chip package structure according to claim 11, wherein a material of the electrodes comprises at least one of platinum, copper, and titanium, and a material of the bumps comprises gold and nickel.

13. A chip package structure, comprising:
a substrate;
a plurality of electrodes, wherein each of the electrodes comprises:
a bottom portion, disposed on the substrate; and
an annular element, comprising:
a first metal ring, disposed on the bottom portion; and
a second metal ring, disposed on the bottom portion and connected to an inside of the first metal ring, wherein the second metal ring and the bottom portion define a containing recess;
a chip, disposed above the substrate, and having an active surface facing the substrate and a plurality of first pads disposed on the active surface; and
a plurality of bumps, respectively disposed on the first pads and respectively inserted into the containing recesses, wherein a melting point of the electrodes is higher than a melting point of the bumps.

14. The chip package structure according to claim 13, wherein a CTE of the first metal ring of each of the electrodes is lower than a CTE of the second metal ring of the electrode.

15. The chip package structure according to claim 13, wherein a material of the first metal ring and the second metal ring is a shape memory alloy.

16. The chip package structure according to claim 13 further comprising a plurality of UBM layers respectively connecting the bumps and the first pads.

17. The chip package structure according to claim 13, wherein a width of the bump in a direction parallel to the active surface is equal to or small than an internal diameter of the annular element.

18. The chip package structure according to claim 13, wherein the annular element is a polygonal annular element, a circular annular element, or an oval annular element.

19. The chip package structure according to claim 13, wherein each of the electrodes further comprises a conductive pole disposed on the bottom portion and located within the containing recess, and the conductive pole is kept a distance away from the annular element.

20. The chip package structure according to claim 13 further comprising a resin, wherein the resin is disposed between the substrate and the chip and encapsulates the electrodes and the bumps.

21. The chip package structure according to claim 13, wherein the substrate has a first surface and a second surface opposite to each other, the electrodes are disposed on the first surface, the chip package structure further comprises a plurality of conductive vias, the conductive vias pass through the substrate and are extended from the first surface to the second surface, and the conductive vias are electrically connected to the electrodes.

22. The chip package structure according to claim 13, wherein the bumps are respectively bonded with the electrodes through chemical bonding.

23. The chip package structure according to claim 22, wherein a material of the electrodes comprises at least one of copper and nickel, and a material of the bumps comprises stannum.

24. The chip package structure according to claim 13, wherein the bumps are respectively bonded with the electrodes through physical contact.

25. The chip package structure according to claim 24, wherein a material of the electrodes comprises at least one of platinum, copper, and titanium, and a material of the bumps comprises gold and nickel.

26. A chip package structure, comprising:
a substrate;
a plurality of electrodes, wherein each of the electrodes comprises:
a bottom portion, disposed on the substrate; and
an annular element, disposed on the bottom portion, wherein the bottom portion and the annular element define a containing recess;
a chip, disposed above the substrate and having an active surface facing the substrate and a plurality of first pads disposed on the active surface;
a plurality of bumps, respectively disposed on the first pads and respectively inserted into the containing recesses; and
a resin, disposed between the substrate and the chip, and encapsulating the electrodes and the bumps, wherein the resin supplies a pressure to each of the annular elements to bend a free end of the annular element which is away from the bottom portion towards the corresponding bump and hold the bump.

27. The chip package structure according to claim 26 further comprising a plurality of UBM layers respectively connecting the bumps and the first pads.

28. The chip package structure according to claim 26, wherein a width of the bump in a direction parallel to the active surface is equal to or smaller than an internal diameter of the annular element.

29. The chip package structure according to claim 26, wherein the annular element is a polygonal annular element, a circular annular element, or an oval annular element.

30. The chip package structure according to claim 26, wherein the substrate has a first surface and a second surface opposite to each other, the electrodes are disposed on the first surface, the chip package structure further comprises a plurality of conductive vias, the conductive vias pass through the substrate and are extended from the first surface to the second surface, and the conductive vias are electrically connected to the electrodes.

31. The chip package structure according to claim 26, wherein the bumps are respectively bonded with the electrodes through physical contact.

32. The chip package structure according to claim 26, wherein a material of the electrodes comprises at least one of platinum, copper, and titanium, and a material of the bumps comprises gold and nickel.
